(19) United States
(12) Patent Application Publication
(10) Pub. No.: US 2008/0057738 A1
(43) Pub. Date: Mar. 6, 2008

(54) ATOMIC LAYER DEPOSITION APPARATUS AND METHOD FOR MANUFACTURING SEMICONDUCTOR DEVICE USING THE SAME

(75) Inventor: June Woo LEE, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/847,951

(22) Filed: Aug. 30, 2007

(30) Foreign Application Priority Data
Aug. 31, 2006 (KR) 10-2006-0083911

(51) Int. Cl. H01L 21/31; B05C 11/00

(52) U.S. Cl. 438/778; 118/670; 257/E21.24

(57) ABSTRACT

An apparatus for atomic layer deposition (ALD) and methods for manufacturing a semiconductor device using the same. In one example embodiment, an ALD apparatus includes a heater, a plasma device, a distance control unit, and a controller. The heater is configured to have a semiconductor substrate mounted thereon. The plasma device is positioned opposite an upper side of the heater. The distance control unit is configured to control a distance between the plasma device and the semiconductor substrate. The controller is configured to determine whether the semiconductor substrate has been plasma-damaged by the plasma device.

### CROSS-REFERENCE TO RELATED APPLICATION

This application claims priority to Korean Application No. 10-2006-0083911, filed on Aug. 31, 2006, which is incorporated herein by reference in its entirety.

### BACKGROUND

1. Field of the Invention

The invention relates to an atomic layer deposition (ALD) apparatus and methods for manufacturing semiconductor devices using the same.

2. Description of the Related Art

In general, an atomic layer deposition (ALD) apparatus maintains precursor materials separate during the deposition process. ALD methods are self-limited and based on surface reactions. ALD methods have some advantages over other types of deposition methods and have been employed where film thicknesses and uniformity are to be precisely controlled. One example where ALD methods can be employed is in the formation of a gate insulation layer.

Plasma enhanced atomic layer deposition (PEALD) can also be employed to improve density of films in order to obtain a film corresponding to a thermal oxide film. However, PEALD can result in damage to the substrate of a film due to an influence of plasma radical that is applied to the film for an extended time. Employing an ALD method that employs a plasma device that is relatively distant from a semiconductor substrate may reduce the plasma damage at an initial stage of forming a film, but after the film is partially formed, a plasma passivation effect can results in degradation of plasma efficiency.

### SUMMARY OF EXAMPLE EMBODIMENTS

In general, example embodiments of the invention relate to an atomic layer deposition (ALD) apparatus capable of enhancing favorable film characteristics by increasing density of a film while reducing plasma damage at an initial stage of film formation in plasma enhanced atomic layer deposition (PEALD), and methods for manufacturing semiconductor devices using the same. At an initial stage of the PEALD, the substrate and the thin films are protected against the plasma damage by positioning a plasma device relatively distant from the semiconductor substrate, and after the film formation, the film quality can be improved by repositioning the plasma device relatively close to the semiconductor substrate.

In one example embodiment, an ALD apparatus includes a heater, a plasma device, a distance control unit, and a controller. The heater is configured to have a semiconductor substrate mounted thereon. The plasma device is positioned proximate the semiconductor substrate. The distance control unit is configured to control a distance between the plasma device and the semiconductor substrate. The controller is configured to determine whether the semiconductor substrate has been plasma-damaged by the plasma device.

In another example embodiment, a method for manufacturing a semiconductor device using an atomic layer deposition apparatus includes mounting a semiconductor substrate within an ALD apparatus, depositing an atomic layer of a film on the semiconductor substrate using a plasma device that is positioned at a first distance away from the semiconductor substrate, positioning the plasma device at a second distance from the semiconductor substrate when the semiconductor substrate is determined not to be damaged by the plasma device at the first distance, and continuously depositing the atomic layer of the film at the second distance. In this example method, the second distance is less than the first distance.

### BRIEF DESCRIPTION OF THE DRAWINGS

Aspects of example embodiments of the invention will become apparent from the following description of example embodiments given in conjunction with the accompanying drawings, in which:

FIGS. 1 and 2 are conceptual views showing an example atomic layer deposition (ALD) apparatus;

FIG. 3 is a conceptual view of an example deposition cycle of the example ALD apparatus of FIGS. 1 and 2;

FIG. 4 is a sectional view of an example process for forming a gate insulation layer using the example ALD apparatus of FIGS. 1 and 2; and

FIG. 5 is a sectional view of an example process for forming a barrier metal using the example ALD apparatus of FIGS. 1 and 2.

### DETAILED DESCRIPTION OF EXAMPLE EMBODIMENTS

Hereinafter, an example atomic layer deposition (ALD) apparatus and example methods for fabricating semiconductor devices using the same will be described in detail with reference to the accompanying drawings.

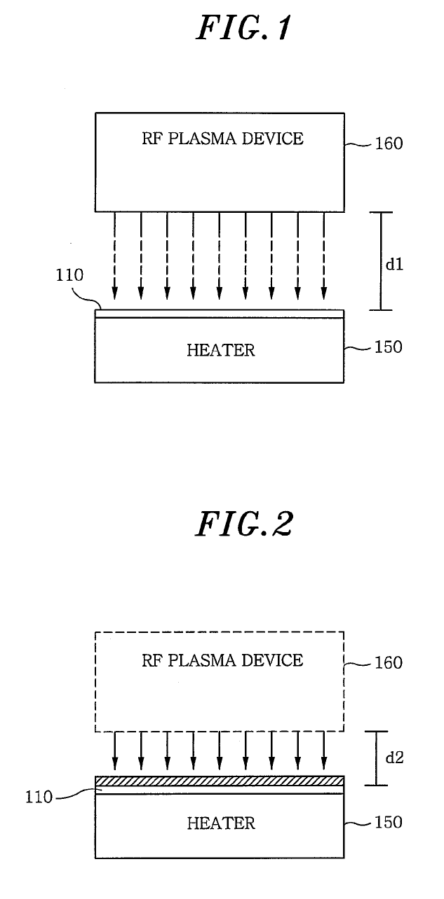

FIGS. 1 and 2 disclose an example ALD apparatus. The example ALD apparatus of FIGS. 1 and 2 includes a heater 150 on an upper side of which a semiconductor substrate 110 can be mounted. A plasma device 160 is positioned opposite the semiconductor substrate 110 mounted on the heater 150. The example ALD apparatus also includes a distance control unit (not shown) that is configured to control the distance between the plasma device 160 and the semiconductor substrate 110. The example ALD apparatus further includes a controller (not shown) that is configured to determine whether the semiconductor substrate 110 has been plasma-damaged by the plasma device 160.

With specific reference now to FIG. 1, when the controller determines that the semiconductor substrate has been plasma-damaged by the plasma device 160, the controller is configured to employ the distance control unit to maintain the plasma device 160 at a first distance (d1) away from the semiconductor substrate 110 to prevent damage of the semiconductor substrate 110.

With specific reference now to FIG. 2, if the controller determines that the semiconductor substrate 110 is not plasma-damaged, the controller is configured to employ the distance control unit to position the plasma device 160 at a second distance (d2) away from the semiconductor substrate 110. The second distance (d2) is less than the first distance (d1), as disclosed in FIGS. 1 and 2.

The example ALD apparatus of FIGS. 1 and 2 is configured, at an initial stage of a plasma enhanced atomic layer deposition (PEALD) method, to protect the semiconductor substrate 110 and a thin film of a semiconductor device from plasma damage. Then, after initial film formation, the example ALD apparatus is configured to decrease the distance between the semiconductor device and the plasma device, thus resolving the plasma passivation effect to achieve improvement of film quality by plasma.

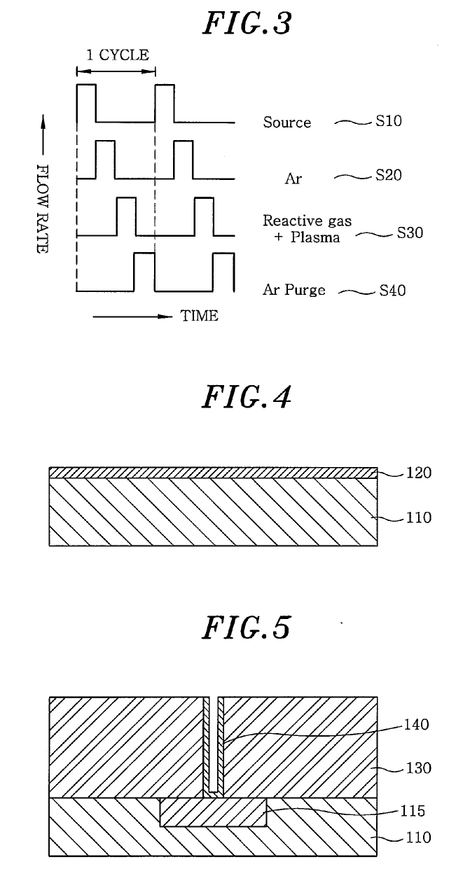

FIG. 3 discloses an example deposition cycle of the example ALD apparatus of FIGS. 1 and 2. As shown in FIG. 3, first, a source is purged (S10). Then, Ar gas is also purged (S20). Next, plasma is formed by the plasma device with a reactive gas (S30). Thereafter, Ar gas is purged again (S40).

FIG. 4 discloses details of an example method for forming a gate insulation layer using the example ALD apparatus of FIGS. 1 and 2. As shown in FIG. 1, the semiconductor substrate 110 of FIG. 4 can be mounted within the example ALD apparatus of FIGS. 1 and 2. Next, ALD of a film 120 can performed on the semiconductor substrate 110 at the first distance (d1) away from the plasma device 160. The first distance (d1) is a sufficient distance for the semiconductor substrate 110 to not be plasma-damaged by the plasma device 160. The film 120 can be a gate insulating layer, but is not limited to being a gate insulating layer.

Subsequently, when the semiconductor substrate 110 is determined not to be plasma-damaged by the plasma device 160 at the distance (d1), the plasma device 160 can be positioned at the second distance (d2) from the semiconductor substrate 110, as disclosed in FIG. 2. Thereafter, the ALD of the film 120 is continuously performed at the distance (d2).

Additional details for the method of forming the film 120 are as follows. A deposition temperature can be between about 150° C. and about 400° C. About 150° C. is the lowest temperature condition for performing the example ALD method, and in case of a BEOL (Back End Of Line) method, the device may be thermally attacked if the temperature rises above about 400° C. The example method can be performed at a pressure of between about 0.1 Torr and about 5.0 Torr. Each cycle of the method can last between about 1 second and about 3 seconds. A minimum time for applying a saturation mechanism can be about one second. Plasma power can be between about 50 W and about 1000 W.

In one example embodiment, at (S10), Ar of between about 50 sccm and about 200 sccm is purged. Then, at (S20), SiH4 of between about 50 sccm and about 150 sccm is purged. Next, at (S30), H2O of between about 100 sccm and about 2,000 sccm is purged. Using the example apparatus and example method discussed above, at the initial stage of PEALD, the substrate and the gate insulating layer can be protected against plasma damage by positioning a plasma device relatively distant from the semiconductor substrate, and after formation of the gate insulating layer, the film quality can be improved by repositioning the plasma device relatively close to the semiconductor substrate.

FIG. 5 discloses an example method for forming a barrier metal using the example ALD apparatus of FIGS. 1 and 2. As disclosed in the example method of FIG. 5, a barrier metal 140 for metal wiring is formed. A lower metal wiring 115 may be formed in the semiconductor substrate 110, and an interlayer insulating layer 130 can be formed on the semiconductor substrate 110.

The interlayer insulation layer 130 is etched to form a via hole. A method for forming the barrier metal 140 can then be performed on the sidewall of the via hole by using the example ALD apparatus of FIGS. 1 and 2. The example method of FIG. 5 may employ the manufacturing method discussed above in connections with FIGS. 1-4.

Using the example apparatus of FIGS. 1 and 2 and the example method of FIG. 5 as discussed above, at the initial stage of PEALD, the substrate and the barrier metal can be protected from plasma damage by positioning a plasma device relatively distant from the semiconductor substrate, and after formation of the barrier metal, the film quality can be and after formation of the gate insulating layer, the film quality can be improved by repositioning the plasma device relatively close to the semiconductor substrate.

While the invention has been shown and described with respect to some example embodiments, various changes and modifications may be made without departing from the scope of the invention as defined in the following claims.

What is claimed is:

1. An ALD apparatus comprising:
a heater configured to have a semiconductor substrate mounted thereon;
a plasma device positioned proximate the semiconductor substrate;
a distance control unit configured to controls a distance between the plasma device and the semiconductor substrate; and
a controller configured to determine whether the semiconductor substrate has been plasma-damaged by the plasma device.

2. The apparatus of claim 1, wherein when the controller determines that the semiconductor substrate has been plasma-damaged by the plasma device, the controller is configured to employ the distance control unit to maintain the plasma device at a first distance away from the semiconductor substrate in order to prevent damage of the semiconductor substrate.

3. The apparatus of claim 2, wherein when the controller determines that the semiconductor substrate has not been plasma-damaged, the controller is configured to employ the distance control unit to position the plasma device at a second distance away from the semiconductor substrate, the second distance being less than the first position.

4. A method for manufacturing a semiconductor device using an ALD apparatus, the method comprising:
mounting the semiconductor substrate within an ALD apparatus;
depositing an atomic layer of a film on the semiconductor substrate using a plasma device that is positioned at a first distance away from the semiconductor substrate;
positioning the plasma device at a second distance, that is less than the first distance, from the semiconductor substrate when the semiconductor substrate is determined to not be plasma-damaged by the plasma device at the first distance; and
continuously depositing the atomic layer of the film at the second distance.

5. The method of claim 4, wherein the film comprises a gate insulating layer.

6. The method of claim 5, wherein the depositing of the atomic layer of the film is performed at a deposition temperature of between about 150° C. and about 400° C.

7. The method of claim 5, wherein the depositing of the atomic layer of the film is performed at a pressure of between about 0.1 Torr and about 5.0 Torr with a plasma power within a range of between about 50W to about 1,000 W.

8. The method of claim 5, wherein the depositing of the atomic layer of the film comprises:
purging argon (Ar) of between about 50 sccm and about 200 sccm;
purging SiH4 of between about 50 sccm and about 150 sccm; and
purging H2O of between about 100 sccm and about 2,000 sccm.

9. The method of claim 4, wherein the film comprises a barrier metal.
